(19) United States
(12) Patent Application Publication
(10) Pub. No.: US 2015/0016030 A1
(43) Pub. Date: Jan. 15, 2015

(54) REDUCING APPEARANCE OF PHYSICAL DAMAGE ON COSMETIC SURFACES

(71) Applicant: Apple Inc., Cupertino, CA (US)

(72) Inventors: Lucy E. Browning, San Francisco, CA (US); Christopher D. Prest, San Francisco, CA (US); Stephen B. Lynch, Portola Valley, CA (US)

(21) Appl. No.: 13/941,232

(22) Filed: Jul. 12, 2013

(51) Int. Cl. H05K 5/02; C23C 28/00

(52) U.S. Cl. CPC H05K 5/0243; C23C 28/00
USPC 361/679.01; 427/331; 428/34.1

(57) ABSTRACT

The described embodiments relate generally to cosmetic surfaces and associated treatments to form cosmetic surfaces. Cosmetic surface treatments as described herein both increase durability and decrease the appearance of physical damage through implementation of an intermediate barrier layer having a first physical attribute (e.g., color of barrier layer) of a predetermined relationship with a second physical attribute of a second layer (e.g., color of a cosmetic layer). The intermediate barrier layer separates the second layer (e.g., a cosmetic or external layer) from internal material supporting both. The first physical attribute may be chosen to be of a similar appearance to the second physical attribute (e.g., matching and/or somewhat closely matching in color) such that physical damage to the cosmetic layer is made less visible.

### FIELD OF THE DESCRIBED EMBODIMENTS

The described embodiments relate generally to cosmetic surfaces and more particularly to reducing the appearance of physical damage on cosmetic surfaces.

### BACKGROUND

As technology advances, product designs in general, and designs for mobile products in particular, concentrate on aesthetics and durability. Durable metal housings for products typically receive surface treatments to alter physical appearance and characteristics which increase the aesthetic quality perceived by a user. For example, anodized aluminum in particular is a conventional manner in which to provide a cosmetic surface with reasonable durability having unique aesthetic characteristics. Different colors may be applied through dyes for cosmetic appeal and sealing techniques may further be applied for durability. However, physical damage, such as damage from impacts, scratches, gouges, and other similar damage may be highly visible due to the contrasting nature of a base substrate (e.g., aluminum) and it's surface treatment (e.g., color, texture, etc.). Absent additional external physical barriers, which would otherwise detract from cosmetic appeal of an elegant surface design, improvements are needed in surface treatments which allow a cosmetic appearance to endure, at least partially, after physical damage to the surface.

Therefore, what is desired is a reliable way to reduce the appearance of physical damage, such as scratches, on cosmetic surfaces.

### SUMMARY OF THE DESCRIBED EMBODIMENTS

This paper describes various embodiments that relate to increasing the durability of a cosmetic surface. In one embodiment, a housing for an electronic device is described. The housing includes a substrate characterized as having a first color. The housing also includes an oxide layer characterized as having a second color different than the first color. The oxide layer has an outer surface corresponding to an exterior surface of the housing. The housing also includes a barrier layer positioned between the oxide layer and the substrate. The barrier layer is characterized as having the second color and a hardness value that prevents a break in the oxide layer from exposing the substrate providing a continuous second color at the exterior surface of the housing.

According to another embodiment, an electronic device is described. The electronic device includes a housing that includes a metallic substrate having a surface. The metallic substrate is characterized as having a first color. The housing also includes a cosmetic layer having an outer surface corresponding to an exterior surface of the housing. The cosmetic layer is characterized as having a second color different than the first color. The housing additionally includes a barrier layer positioned between the surface of the substrate and the cosmetic layer. The barrier layer has a hardness value that prevents a break in the oxide layer from exposing the first color of the metallic substrate. The barrier layer is characterized as having a third color that substantially corresponds to the second color such that the break in the oxide layer exposes the barrier layer and provides a continuous second color at the exterior surface of the housing.

According to yet another embodiment, a method of forming a cosmetic coating on a surface of a substrate having a first color is described. The method includes forming a barrier layer on the surface of the substrate. The barrier layer is characterized as having a hardness value and having a second color different from the first color. The method also includes forming a metallic layer over the barrier layer. The method additionally includes converting at least a portion of the metallic layer to a dyed metal oxide layer. The dyed metal oxide layer has an outer surface corresponding to an exterior surface of the cosmetic coating and is characterized as having the second color. The hardness value of the barrier layer prevents a break in the metal oxide layer from exposing the substrate. The second color of the barrier layer provides a continuous second color at the exterior surface of the cosmetic coating.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments may be better understood by reference to the following description and the accompanying drawings. These drawings are not necessarily drawn to scale. Additionally, advantages of the described embodiments may be better understood by reference to the following description and accompanying drawings. These drawings do not limit any changes in form and detail that may be made to the described embodiments. Any such changes do not depart from the spirit and scope of the described embodiments.

FIG. 1 shows a perspective view of a housing of a personal electronic device.

FIG. 2A shows a cross-sectional view of a portion of the housing of FIG. 1 having a conventional surface treatment applied.

FIGS. 2B-2C show a cross-sectional view of a portion of the housing of FIG. 1 depicting physical damage to the conventional surface treatment.

FIG. 3 shows a cross-sectional view of a portion of a housing having an exemplary surface treatment applied.

FIG. 4 shows a cross-sectional view of a portion of the housing of FIG. 3 depicting physical damage to the exemplary surface treatment.

FIGS. 5A-5D depict individual process flow steps of a method of applying a cosmetic surface to a base substrate, in accordance with an exemplary embodiment.

FIG. 6 shows flow chart describing a method of applying a cosmetic surface to a base substrate, in accordance with an exemplary embodiment.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

The trend in some modern electronic devices is to increase aesthetics and durability. Durable metal housings for products typically receive surface treatments to alter physical appearance and characteristics which increase the aesthetic quality perceived by a user. For example, metal oxide is a conventional manner in which to provide a cosmetic surface with reasonable durability having unique aesthetic characteristics. Different colors may be applied to the metal oxide through dyes for cosmetic appeal and sealing techniques may further be applied to the metal oxide for durability. However, physical damage, such as damage from impacts, scratches, gouges, and other similar damage may be highly visible due to the contrasting nature of a base substrate (e.g., aluminum) and it's surface treatment (e.g., color, texture, etc.).

According to exemplary embodiments, cosmetic surface treatments both increase durability and decrease the appearance of physical damage through implementation of an intermediate barrier layer having a first physical attribute (e.g., color of barrier layer) of a predetermined relationship with a second physical attribute of a second layer (e.g., color of a cosmetic layer). The intermediate barrier layer may be applied in a number of differing manners, using conventional and/or non-conventional techniques. The intermediate barrier layer is intermediate in that it separates the second layer (e.g., a cosmetic or external layer) from an internal layer (e.g., base substrate layer). The first physical attribute may be chosen to be of a similar appearance to the second physical attribute (e.g., matching and/or somewhat closely matching in color). According to other embodiments, the first physical attribute may be chosen to be of a contrasting appearance to the second physical attribute (e.g., complementary or contrasting in color). Hereinafter the aspects and benefits of exemplary surface treatments are described in detail with comparison to conventional surface treatment techniques.

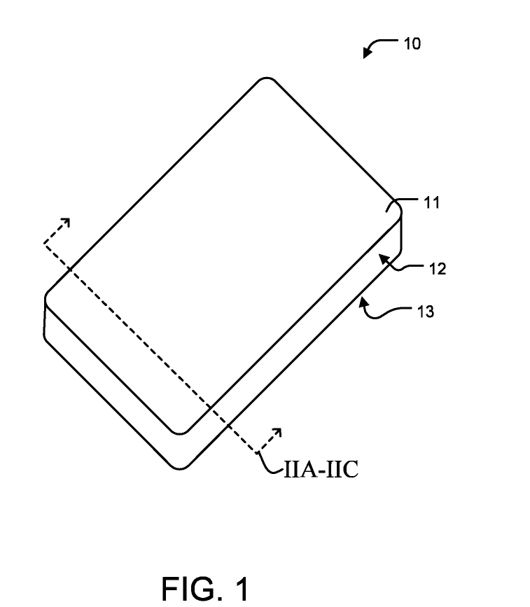

FIG. 1 shows a perspective view of a housing 10 of a personal electronic device. The housing 10 can be formed of any suitable material, including metals such as aluminum, steel, stainless steel, copper, and/or alloys. In some embodiments, housing 10 includes a non-metal material, such as plastic, or includes non-metal portions. The housing 10 may have a first surface 11, one or more second or side surfaces 12, and a rear surface 13. The orientation, shape, volume, and arrangement of the surfaces 11, 12, 13 can be varied in any suitable manner without departing from this disclosure. Generally, one of more of the surfaces 11, 12, 13 may have a surface treatment applied thereto. For example, all or portions of one or more surfaces 11, 12, 13 can be made of material, such as aluminum or titanium, that is well suited for an anodized finish surface treatment.

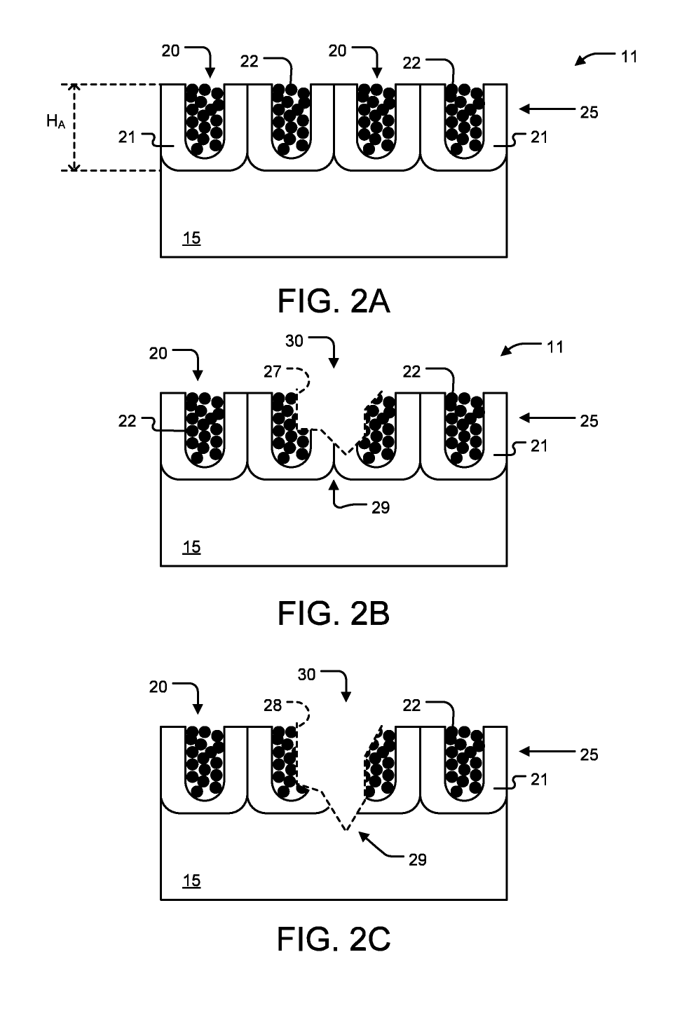

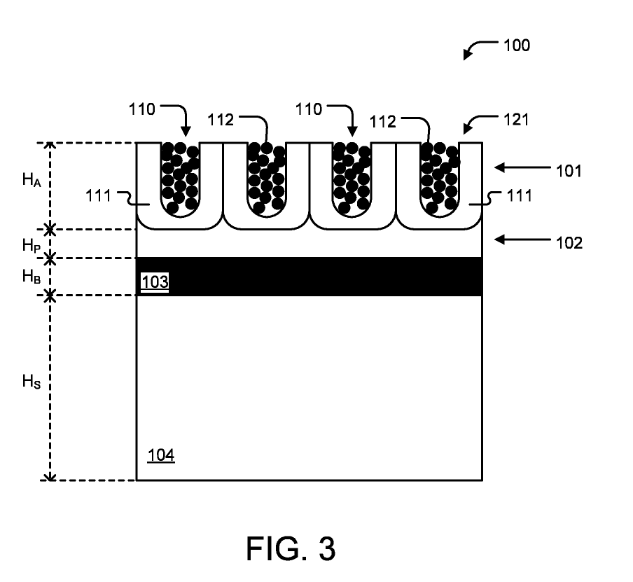

FIG. 2A shows a cross-sectional view of a portion of the housing 10 having a conventional surface treatment applied thereto. As illustrated, the surface 11 includes base substrate material 15, which has been anodized to form an anodized layer 25. The anodized layer 25 may have a total thickness or height H_{A}. The anodized layer 25 includes a porous microstructure that includes a number of anodic oxide pores 21. These pores 21 have a pore cavity 20 formed therein, which may accept dye, sealant, or other material. In this example, dye pigment or dye particles 22 have been deposited or applied to the anodized layer 25 such that pore cavities 20 receive and support the pigment 22. Dye pigment 22 can impart a color to anodized layer 25, as viewed from top of surface 11, which is associated with the color of dye pigment 22. Note that without dye pigment 22, anodized layer 25 can be substantially transparent or translucent, thereby revealing the color of underlying base substrate material 15.

As described above, anodized layer 25 can have a color associated with the color of dye pigment 22. However, if physical damage were to occur which reaches beyond the anodized layer 25, the base material 15 may become visible, even if portions of the anodic oxide pores 21 are intact. FIGS. 2B-2C show a cross-sectional view depicting physical damage to the conventional surface treatment. As shown, physical damage 27 and 28 penetrates a portion of the anodized layer 25. In FIG. 2B, an apparent viewpoint from area 30 shows the underlying portion 29 of substrate 15 through damage anodic oxide pores 21. In FIG. 2C, an apparent viewpoint from area 30 also shows the underlying portion 29 of substrate 15.

As illustrated, physical damage 27, although not entirely penetrating the anodized layer 25, still allows viewing of the contrast in color between dye 22 and the underlying area 29 of the substrate 15. Moreover, deep physical damage 28 also shows the underlying area 29. As such, any user viewing the damage 27, 28 from above the surface 11 would readily be able to discern it. However, according to exemplary embodiments, novel intermediate barrier layers may be formed such that physical damage may be less visible as compared to damage 27, 28 described above.

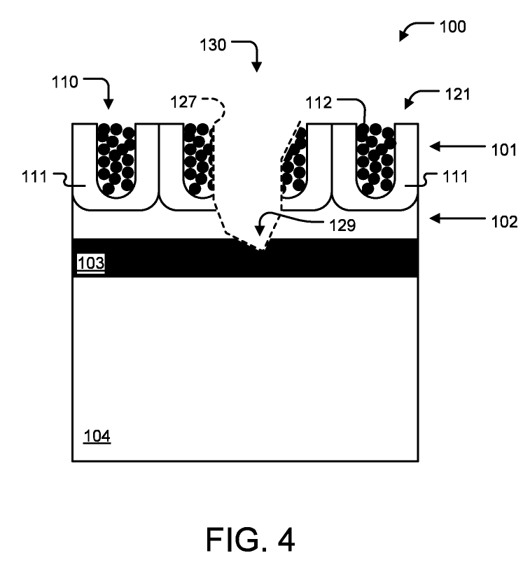

FIG. 3 shows a cross-sectional view of a portion of a housing having an exemplary surface treatment applied. The surface treatment includes a stacked arrangement of layers, generally indicated as 100, which reduce the visibility of physical damage such as scratches. In general, the housing 100 may include a base substrate layer 104 having an overall thickness or height of H_{S}. The base substrate layer 104 may be formed of any suitable material, including, for example, metal, ceramic, laminate, and/or plastic. In some embodiments, the material of base substrate layer 104 is chosen for its structural characteristics. According to one embodiment, the base substrate layer 104 is formed of aluminum or aluminum alloy. According to another embodiment, the base substrate layer 104 is formed of magnesium alloy. According to another embodiment, the base substrate layer 104 is formed of stainless steel. According to still other embodiments, the base substrate layer 104 is formed of a composite material such as a ceramic material. It should be noted, however, that base substrate layer 104 can be formed of any suitable material capable of accepting an intermediate barrier layer 103. For example, base substrate layer 104 can be formed of copper or titanium.

As illustrated, the intermediate barrier layer 103 is arranged on and in contact with the base substrate layer 103. The intermediate barrier layer 103 may have an overall height of thickness of H_{B}. The height H_{B} can have a hardness value and thickness suitable for protecting underlying base substrate layer 104 from physical damage. In some embodiments, height H_{B} can be between about five to fifteen microns according to some embodiments. According to other embodiments, the height H_{B} can be more than about 15 microns. The intermediate barrier layer 103 may be formed of any suitable material, including a metal or metal alloy. In some implementations (e.g., in electroplating), the intermediate barrier layer 103 may be termed a “strike layer.” Generally, intermediate barrier layer 103 protects underlying base substrate layer 104 from physical damage such as scratching and gouging. As such, intermediate barrier layer 103 is typically formed of a material that is harder or more resilient than base substrate layer 103. In addition, the material of intermediate barrier layer 103 can be chosen for its cosmetic characteristics, such as its color. For example, the color of intermediate barrier layer 103 can be chosen to closely match the color of overlying dyed anodized layer 101, which will be described in detail below.

According to one embodiment, the intermediate barrier layer 103 is formed of nickel. According to another embodiment, the intermediate barrier layer 103 is formed of plate nickel or electroless nickel plating (EN). In some embodiments, the plated nickel or EN includes chemical agents, such as phosphorus, to alter the color of the plated nickel or EN. According to another embodiment, the intermediate barrier layer 103 is formed of electrolytic nickel or black electrolytic nickel. According to another embodiment, the intermediate barrier layer 103 is formed of cadmium or black cadmium. According to another embodiment, the intermediate barrier layer 103 is formed of zinc nickel or black zinc nickel. According to yet other embodiments, the intermediate barrier layer is formed of copper. It should be understood that the above examples are provided to aid in the understanding of comparisons between physical attributes (e.g., mechanical qualities and/or cosmetic qualities) of the intermediate barrier layer 103 and do not include all possible material compositions.

As further illustrated, a plating or buffer layer 102 is arrange on and in contact with the intermediate barrier layer 103. The buffer layer 102 may have a height or thickness of H_{P}. Height H_{P} may vary according to suitable desired implementation of an anodizing process. In one embodiment, the buffer layer 102 is formed of aluminum or an aluminum alloy plated onto the intermediate barrier layer 103.

As further illustrated, an anodized layer 101 is arranged on the buffer layer 102. The anodized layer 101 may be formed through an anodizing process, which anodizes and converts material from an originally plated buffer layer (discussed in more detail with reference to FIG. 7). The anodized layer 101 may also be termed a cosmetic layer. The anodized layer 101 may have a total thickness or height H_{A}. Height H_{A} may vary according to any desired anodizing process. According to at least one embodiment, the height H_{A} may be between about five to thirty microns. The anodized layer 101 includes a porous microstructure that includes a number of anodic oxide pores 111. These pores 111 have pore cavities 110 formed therein, which may accept dye, sealant, or other material as described with reference to FIG. 2A. In at least one embodiment, dye pigment 112 has been deposited or applied to the anodized layer 101 such that pore cavities 110 receive and support the pigment 112.

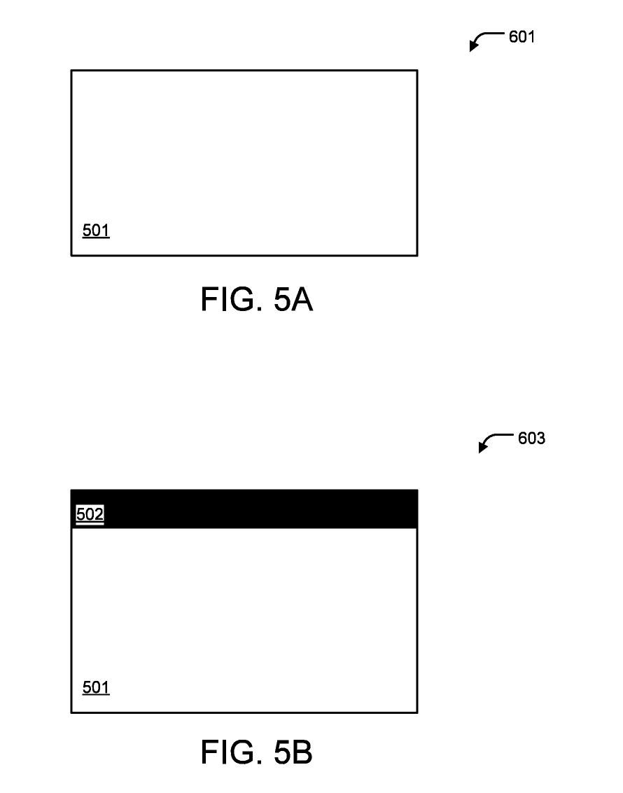

Dye pigment 112 imparts a color to anodized layer 101. However, if physical damage were to occur which reaches beyond the anodized layer 101 and at least partially through the buffer layer 102, the intermediate barrier layer 103 may become visible. As described above, the intermediate barrier layer 103 may have physical attributes, such as mechanical and cosmetic qualities, associated therewith. For example, intermediate barrier layer 103 may be harder or more resilient than underlying base layer 104 such that base layer 104 is protected from physical damage or physical damage to base layer 104 is minimized. In addition, intermediate barrier layer 103 may have a certain cosmetic quality, such as color, associated therewith. In at least one embodiment, the first physical attribute is a color of the intermediate barrier layer 103. In some embodiments, the color of the intermediate barrier layer 103 is black or a shade of grey. Furthermore, the dye pigment 112 may have a second physical attribute. In at least one embodiment, the second physical attribute is a color of the dye pigment 112. In some embodiments, the color of the dye pigment 112 is also black of a shade of grey. The first physical attribute may be chosen to be of a similar appearance to the second physical attribute (e.g., matching and/or somewhat closely matching in color). According to other embodiments, the first physical attribute may be chosen to be of a contrasting appearance to the second physical attribute (e.g., complementary or contrasting in color). As such, a number of color combinations may be chosen according to a predetermined or desired relationship between the intermediate barrier layer 103 and the dye pigment 112 (or alternatively, a native color of the anodized layer 101). This is described in more detail with reference to FIG. 4.

FIG. 4 shows a cross-sectional view of a portion of the housing of FIG. 3 depicting physical damage 127 to the exemplary surface treatment. As shown, physical damage 127 penetrates the anodized layer 101 and a portion of the buffer layer 102. An apparent viewpoint from area 130 shows the underlying portion 129 of intermediate barrier layer 103. As such, if the first and second physical characteristics are chosen to be about the same color, the physical damage 127 may be less visible as compared to FIGS. 2B-2C. More specifically, visibility of the area 129 would show the color of area 129 (e.g., black or a shade of grey). If the anodized layer 101 has a color due to dye pigment 112 that is about the same color as intermediate barrier layer 103, visibility of the damage 127 would be reduced. Thus, any color differences between base substrate layer 104 and dyed anodized layer 101 would not be visibly apparent. That is, the color of housing 100, as viewed from top surface 121, would appear to be continuous. In addition, intermediate barrier layer 103 can be mechanically hard or resilient, thereby preventing or minimizing exposure of underlying base substrate layer 104.

In some embodiments, buffer layer 102 can be a different color than anodized layer 101. For example, anodized layer can be dyed to a black or grey color while buffer layer 102 can be a silver or light grey color, such as the color of aluminum or aluminum alloy. In these situations, it can be beneficial for the thickness of buffer layer 102 to be minimized to minimize the amount of exposure of buffer layer 102 due to physical damage 127. In addition, the material of buffer layer 102 can be chosen such that it is mechanically softer than intermediate barrier layer 103. This way, physical damage 127 will tend to penetrate through buffer layer 102 and reach intermediate barrier layer 103, thereby exposing the color of intermediate barrier layer. For example, intermediate barrier layer 103 can a dark colored plated nickel or zinc nickel containing layer while buffer layer 102 can be a lighter colored pure aluminum layer. Since pure aluminum is generally softer than plated nickel or zinc nickel, physical damage such as a scratch or gouge will generally abrade through the softer pure aluminum layer and stop at the harder nickel or zinc nickel containing layer. This reduces likelihood that the lighter colored pure aluminum layer will be visible when the surface of housing 100 is scratched or gouged.

Although described as including black and/or shades of grey in some embodiments, it should be understood that any achievable color combination is applicable to exemplary embodiments. For example, a reddish, orange, or yellow color for dye pigment 112 may be combined with a copper material for intermediate barrier layer 103 to reduce visibility of physical damage. Moreover, contrasting color combinations are also applicable. For example, complementary but contrasting colors may be combined to allow for subtle engraving on a surface of a treated substrate. Heavily contrasting color combinations may be implemented to aid in discerning how easily a proposed surface treatment (e.g., layers 101 and 102) is damaged (i.e., by increasing the visibility of damage). As such, the present disclosure should not be limited by the particular examples given herein, but should be applicable to all suitable variations.

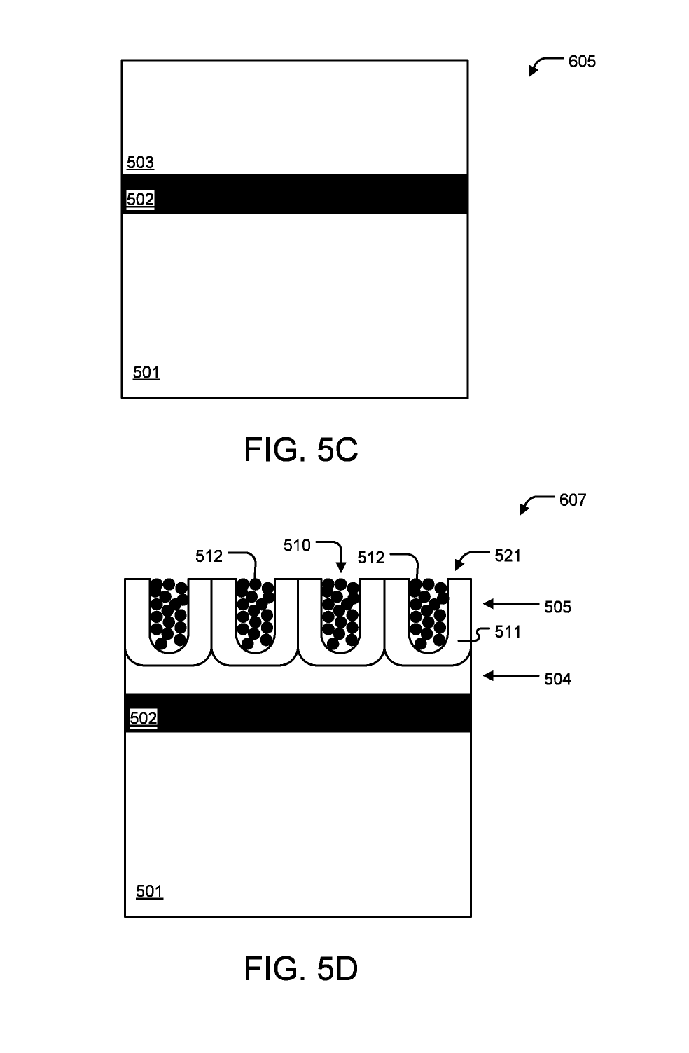

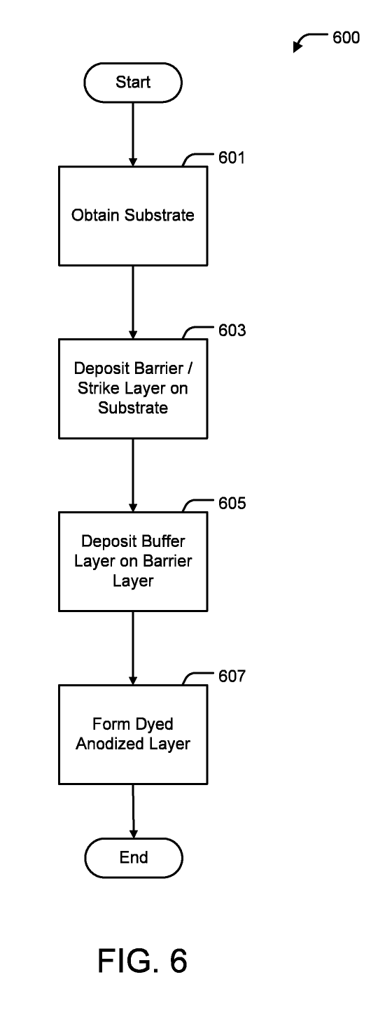

Turning to FIGS. 5A-6, a method of applying a cosmetic surface to a base substrate is described in detail. FIGS. 5A-5D depict individual process flow steps of a method 600 of applying a cosmetic surface to a base substrate, in accordance with an exemplary embodiment. FIG. 6 shows flow chart describing the method 600.

With reference to FIG. 6, the method 600 begins by obtaining, receiving, and/or otherwise producing a substrate for processing at block 601 (FIG. 5A). The substrate 501 may be formed of any suitable material, including aluminum or stainless steel. The substrate 501 may, according to some embodiments, be substantially similar to base substrate layer 104. Thereafter, the method 600 includes depositing and/or forming a barrier layer on the substrate 501 (FIG. 5B) at block 603. The barrier layer 502 may be deposited for formed using any suitable technique, including electro-plating, physical vapor deposition (PVD), and sputter deposition. Other techniques may also be applicable depending on the composition of the substrate 501 and the barrier layer 502. The barrier layer 502 may be substantially similar to intermediate buffer layer 103 in some embodiments.

Subsequently, the method 600 includes depositing or forming a plating or buffer layer 503 on the barrier layer 502 (thereby rendering the barrier layer an “intermediate” barrier layer; FIG. 5C) at block 605. The buffer layer 503 may be formed of any suitable material, including aluminum or an aluminum alloy. Thereafter, the method 600 includes forming a dyed anodized layer by anodizing the buffer layer and dyeing the anodized layer (FIG. 5D) at block 607. In some embodiments the anodized layer is subsequently optionally sealed using a sealing process. Generally, block 607 includes any suitable anodizing process by which a portion of the buffer layer 503 forms an anodized layer 505 while a portion remains as buffer layer 504. Anodic pores 511 of anodized layer 505 are subsequently partially or fully filled with dye pigment 512 using any suitable dying process. Buffer layer 504 is substantially similar to buffer layer 102 and anodized layer 505 is substantially similar to anodized layer 101. As described above, physical characteristics (e.g., color) of the dyed anodized layer 505 and the intermediate barrier layer 502 may have a predetermined relationship (i.e., color matching, complementary colors, contrasting colors, etc.). For example, the dyed anodized layer 505 and the intermediate barrier layer 502 can have substantially the same color such that the color of housing 100, as viewed from top surface 521, would appear to be continuous.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

1-20. (canceled)

21. A housing for an electronic device, the housing comprising:
a substrate characterized as having a first color;
an oxide layer characterized as having a second color different than the first color and comprising an outer surface corresponding to an exterior surface of the housing; and
a barrier layer positioned between the oxide layer and the substrate, the barrier layer characterized as having the second color and a hardness value that prevents a break in the oxide layer from exposing the first color of the substrate providing a continuous second color at the exterior surface of the housing.

22. The housing of claim 21, wherein the oxide layer comprises a porous microstructure having a plurality of dye particles embedded therein, the dye particles imparting the second color to the oxide layer.

23. The housing of claim 21, wherein the substrate is formed of aluminum or stainless steel and the barrier layer comprises substantially pure aluminum.

24. The housing of claim 21, wherein the second color is substantially black or substantially grey.

25. The housing of claim 21, wherein the break in the oxide layer extends from the outer surface, through the oxide layer, and to the barrier layer to expose the second color of the barrier layer.

26. The housing of claim 21, wherein the barrier layer is formed of at least one of nickel, cadmium and zinc.

27. The housing of claim 21, further comprising:
a buffer layer positioned between the barrier layer and the oxide layer, the buffer layer having a hardness value less than the hardness value of the barrier layer.

28. A housing for an electronic device, the housing comprising:
a substrate characterized as having a first color;
an oxide layer characterized as having a second color different than the first color and comprising an outer surface corresponding to an exterior surface of the housing; and
a barrier layer positioned between the oxide layer and the substrate, the barrier layer having a hardness value higher than a hardness value of the substrate protecting the substrate from physical damage, the barrier layer characterized as having the second color preventing a break in the oxide layer from exposing the first color of the substrate providing a continuous second color at the exterior surface of the housing.

29. The housing of claim 28, wherein the barrier layer has a thickness ranging between about 5 micrometers and about 10 micrometers and a thickness of the oxide layer ranges between about 5 micrometers and about 30 micrometers.

30. The housing of claim 28, wherein the substrate comprises at least one of metal, ceramic, laminate material, and plastic.

31. The housing of claim 28, wherein the oxide layer comprises a porous microstructure having a plurality of dye particles embedded therein, the dye particles imparting the second color to the oxide layer.

32. The housing of claim 28, wherein the physical damage includes at least one of scratching or gouging.

33. The housing of claim 28, further comprising:
a buffer layer positioned between the barrier layer and the oxide layer, the buffer layer having a hardness value less than the hardness value of the barrier layer.

34. A part, comprising:
a metal substrate characterized as having a first color;
an oxide layer having dye particles infused therein imparting a second color different than the first color to the oxide layer, the oxide layer comprising an outer surface corresponding to an exterior surface of the part; and
a barrier layer positioned between the oxide layer and the metal substrate, the barrier layer having a hardness value sufficient to prevent a break in the oxide layer from exposing the first color of the metal substrate, the barrier layer characterized as having the second color such that the break in the oxide layer exposes the second color of the barrier layer providing a continuous second color at the exterior surface of the part.

35. The part of claim 34, wherein the barrier layer comprises at least one of nickel, zinc and cadmium.

36. The part of claim 34, further comprising:
a buffer layer positioned between the barrier layer and the oxide layer, the buffer layer having a hardness value less than the hardness value of the barrier layer.

37. The part of claim 36, wherein the buffer layer comprises aluminum.

38. The part of claim 34, wherein the hardness value of the barrier layer is greater than a hardness value of the metal substrate.

39. The part of claim 34, wherein the metal substrate comprises a laminate structure that includes a metal layer.

40. The part of claim 34, wherein the break in the oxide layer extends from the outer surface, through the oxide layer, and to the barrier layer to expose the second color of the barrier layer.
